(19) United States
(12) Patent Application Publication
(10) Pub. No.: US 2005/0269614 A1
(43) Pub. Date: Dec. 8, 2005

(54) Non-junction-leakage 1T-RAM cell

(76) Inventor: Chung-Cheng Tsou, Hsinchu (TW)

Correspondence Address: THOMAS, KAYDEN, HOSTEMEYER & RISLEY LLP, 100 GALLERIA PARKWAY, SUITE 1750, ATLANTA, GA, 30339, US

(21) Appl. No.: 10/863,428

(22) Filed: Jun. 8, 2004

(51) Int. Cl. H01L 27/108; H01L 21/8238

(52) U.S. Cl. 257/296; 438/223

(57) ABSTRACT

Systems and methods for providing a one-transistor random access memory cell include a substrate, a well of a first conductivity type formed in the substrate and coupled to receive a first voltage, a first gate formed on the substrate and coupled to a word line, a doped region of a second conductivity type formed in the well and on a first side of the first gate, and coupled to a bit line, and a second gate formed on the substrate and a second side of the first gate, and coupled to receive a second voltage, wherein the second voltage applied to the second gate forming an inversion region in the well under the second gate. Other systems and methods are also provided.

### BACKGROUND

The present invention relates to semiconductor memories and particularly to a 1T-RAM without junction leakage.

Semiconductor memory is classified according to the type of data storage and the type of data access mechanism provided, and falls mainly into the following two groups, Non-Volatile Memory and Read/Write Memory. Non-volatile Memory (NVM) also known as Read-Only Memory (ROM). Generally, Read-Only Memory (ROM) retains information when the power supply voltage is off. With respect to the data storage mechanism NVM are divided into the following groups: (1) Mask programmed ROM. The required contents of the memory is programmed during fabrication; (2) Programmable ROM (PROM). The required contents are permanently written by burning out internal interconnections, such as fuses, in a one-off procedure; (3) Erasable PROM (EPROM). Data is stored as a charge on an isolated gate capacitor (“floating gate”). Data is removed by exposing the PROM to the ultraviolet light; and (4) Electrically Erasable PROM (EEPROM) also known as Flash Memory. EEPROM is also based on the concept of the floating gate. The contents can be re-programmed by applying suitable voltage to the EEPROM pins. Flash Memory is a significant data storage device for mobile applications.

Read/Write (R/W) memory, is also known as Random Access Memory (RAM). From the point of view of data storage mechanism RAM is divided into two main groups: (1) Static RAM, where data is retained as long as power is supplied; and (2) Dynamic RAM, where data is stored on capacitors and requires a periodic refresh.

In static CMOS, read-write memory data is stored in six-transistor cells. Memory of this type is fast and consumes little static power. The main drawback is that an SRAM cell occupies a significant amount of silicon space. This problem is addressed by dynamic read-write memory (DRAM).

In DRAM, binary data is stored as a charge in a capacitor. The memory cell consists of a storage capacitor and an access transistor as shown in FIG. 1.

DRAM has two fundamental features. One feature is that the DRAM cell occupies significantly less silicon area than the SRAM cell. The size of a DRAM cell is on the order of 8F2, where F is the smallest feature size in a given technology. For F=0.2 μm, the size is 0.32 μm². Another feature is that no static power is dissipated for storing charge in a capacitance.

However, data stored as a charge in a capacitor can be retained only for a limited time due to the leakage current which eventually removes or modifies the charge. Therefore, dynamic memory cells require a periodic refresh of the stored data before unwanted stored charge modifications occur.

Typical storage capacitance has a value of 20 to 50 fF. Assuming that the voltage on a fully charged storage capacitor is V 2.5V, and that the leakage current is I=40 pA, then the time to discharge the capacitor C=20 fF to half the initial voltage can be estimated as
t=(½)·C·V/I=20·10⁻¹⁵·2.5/40·10⁻¹²=0.625 ms

Hence ever memory cell must be refreshed approximately every half millisecond. There is a need for additional refresh circuitry.

FIG. 2A-2D are diagrams depicting a self-refresh apparatus for a semiconductor memory device and signals thereof disclosed in U.S. Pat. No. 6,229,747. Referring to FIG. 2A, the self-refresh state control unit 21 receives a self-refresh command signal and in response to the signal, transmits a self-refresh state signal (sref) having a predetermined pulse width to the self-refresh control unit 214 and self-refresh request control unit 24.

The leakage current monitor unit 210 monitors leakage currents in the memory cell, and sends a refresh active signal (clm_req) according to the monitored result to the self-refresh control unit 214. The leakage current monitor unit 210 comprises total four cell leakage monitor circuits with, as shown in FIG. 2B, a one cell leakage monitor circuit in each bank, and produces the final refresh active signal (clm_req) by logically operating output signals (clmreq0-clmreq3) from each of the cell leakage monitor circuits by means of an OR gate.

Herein, DWL and DBL are respectively a word line and a bit line in cell of the cell leakage monitor circuit, and opctl is a signal for controlling the integrator of the cell leakage monitor circuit.

If one or more signals among cell refresh signals (clmreq0, clmreq1, clmreq2, clmreq3) in one or more cell leakage monitor circuits attain a high state, the refresh active signal (clm_req) in the leakage current monitor unit 210 achieves a high state, and then the signal is input to the self refresh control unit 214.

The leakage current monitor control unit 212 is operated by the activated refresh active signal (clm_req), and outputs the leakage monitor control signals (DWL, DBL, opctl) for deactivating the activated refresh active signal (clm_req). As shown in FIG. 2C, the leakage current monitor control unit 212 comprises the pulse generating unit 212-1 and monitor control signal generating unit 212-2.

If the high-level refresh active signal (clm_req) (shown in FIG. 2D) from the leakage current monitor unit 210 is input to the pulse generating unit 221-1, the input active signal (clm_req) is logically combined with a signal delayed in the delay unit 212-3 by means of the AND gate. As a result, the pulse signal (refsh_req) (shown in FIG. 2D) is input to the leakage monitor control signal control unit 212-2, and activates the leakage monitor control signals (DWL, DBL, opct1), thereby causing the leakage monitor control signal to be a low state.

In FIG. 2A, the self refresh control unit 214 activates the ring oscillator 22 by activating a self-refresh signal (new_sref) by means of the self-refresh state signal (sref) activated while operating in the self-refresh mode and the refresh active signal (clm_req), and deactivates the self-refresh signal (new_sref) by receiving a termination signal (term_req) from D flip-flop 216. Accordingly, the operation of the ring oscillator 22 is disabled until the refresh active signal (clm_req) of the leakage current monitor unit 210 is activated.

The ring oscillator 22 receives the self-refresh signal (new_sref) and outputs a pulse signal (1 μs Period) having a predetermined period to the frequency divider 23. Upon receiving the pulse signal from the ring oscillator 22, the frequency divider 23 produces a signal (f1 μs) having a new pulse period and outputs it to the self-refresh request state control unit 24. The self-refresh request state control unit 24 combines the output of the self-refresh state control unit 21 and the output of the frequency divider 23, and outputs a self-refresh request signal (selfreq) having a predetermined period to the internal row active control unit 25.

The internal row active control unit 25 includes an internal address counter (not shown), and activates the internal low address by means of the self-refresh request signal (selfreq).

The D flip-flop 216 is connected to the uppermost address of the internal row active control unit 25, and outputs a signal (term_req) terminating the self-refresh, when the potential of the uppermost address is changed, to the self-refresh control unit 214.

Although the previously described apparatus have components that can prevent data from being destroyed by cell leakage current, there is still a need for an additional self-refresh circuitry which occupies a certain area.

### SUMMARY OF THE INVENTION

The object of the present invention is to provide a 1T-RAM cell without junction leakage, wherein refresh frequency is reduced significantly.

To achieve the foregoing and other objects, the invention is directed to novel systems and methods that provide in a preferred embodiment a first one-transistor random access memory cell including a substrate, a well of a first conductivity type formed in the substrate and coupled to receive a first voltage, a first gate formed on the substrate and coupled to a word line, a doped region of a second conductivity type formed in the well and on a first side of the first gate, and coupled to a bit line, and a second gate formed on the substrate and a second side of the first gate, and coupled to receive a second voltage, wherein the second voltage applied to the second gate forming an inversion region in the well under the second gate.

Another preferred embodiment of the present invention provides a second one-transistor random access memory cell including a substrate, a well of a first conductivity type formed in the substrate and coupled to receive a first voltage, a first gate formed on the substrate and coupled to a word line, a first doped region of a second conductivity type formed in the well and on a first side of the first gate, and coupled to a bit line, a second gate formed on the substrate and a second side of the first gate, and coupled to receive a second voltage, and a second doped region of the first type in the well under the second gate having a doping concentration lower than that of the well.

Yet another preferred embodiment of the present invention provides a first memory device including a plurality of memory cells wherein data is read from and written into each of the memory cells through bit lines by control signals on word lines. Each of the memory cells includes a substrate, a well of a first conductivity type formed in the substrate and coupled to receive a first voltage, a first gate formed on the substrate and coupled to one of the word lines, a doped region of a second conductivity type formed in the well and on a first side of the first gate, and coupled to one of the bit lines, and a second gate formed on the substrate and a second side of the first gate, and coupled to receive a second voltage, wherein the second voltage applied to the second gate forming an inversion region in the well under the second gate.

Still another preferred embodiment of the present invention provides a second memory device including a plurality of memory cells wherein data is read from and written into each of the memory cells through bit lines by control signals on word lines. Each of the memory cells includes a substrate, a well of a first conductivity type formed in the substrate and coupled to receive a first voltage, a first gate formed on the substrate and coupled to a word line, a first doped region of a second conductivity type formed in the well and on a first side of the first gate, and coupled to a bit line, a second gate formed on the substrate and a second side of the first gate, and coupled to receive a second voltage, and a second doped region of the first type in the well under the second gate having a doping concentration lower than that of the well.

The present invention can also be viewed as providing methods for manufacturing a one-transistor random access memory cell. In this regard, one embodiment of such a method, among others, can be broadly summarized as providing a substrate, forming a well of a first conductivity type in the substrate, implementing Vt implantation to form a low Vt device in the well, forming a first and second gate on the substrate, wherein the second gate is located above the low Vt device and the low Vt device is located on a first side of the first gate, and forming a doped region of a second conductivity type in the well and on a second side of the first gate.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 shows a conventional memory cell including of a storage capacitor and an access transistor.

FIGS. 2A-2D are diagrams showing a conventional self-refresh apparatus for a semiconductor memory device and signals.

FIG. 3 is a block diagram showing a memory device according to a preferred embodiment of the invention.

FIG. 4 shows a side view memory cell in an array according to a first preferred embodiment of the invention.

FIG. 5 shows a side view memory cell in an array according to a second preferred embodiment of the invention.

FIG. 6 shows a side view memory cell in an array according to a third preferred embodiment of the invention.

FIG. 7 shows a side view memory cell in an array according to a fourth preferred embodiment of the invention.

FIGS. 8A-8C are side views showing a series of views of a one-transistor random access memory cells during a manufacturing process according to a preferred embodiment of the invention.

FIGS. 9A-9C are side views showing a series of views of a one-transistor random access memory cells during a manufacturing process according to another preferred embodiment of the invention.

FIGS. 10A and 10B are diagrams showing the operation of the memory cell in FIG. 4.

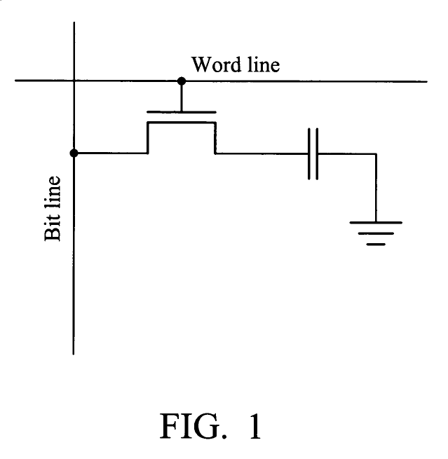

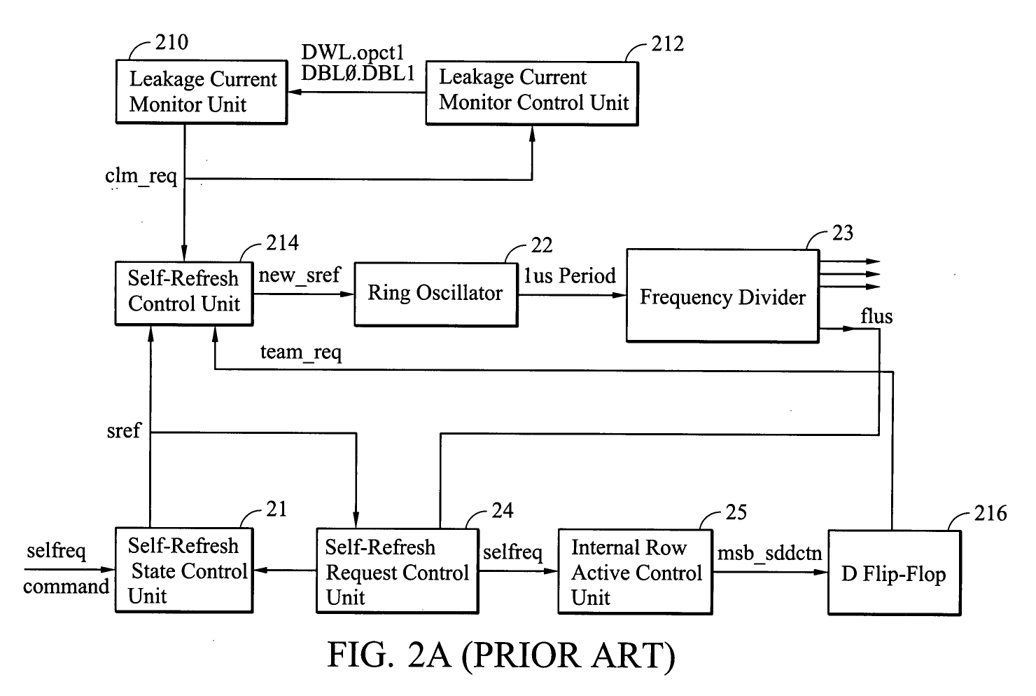

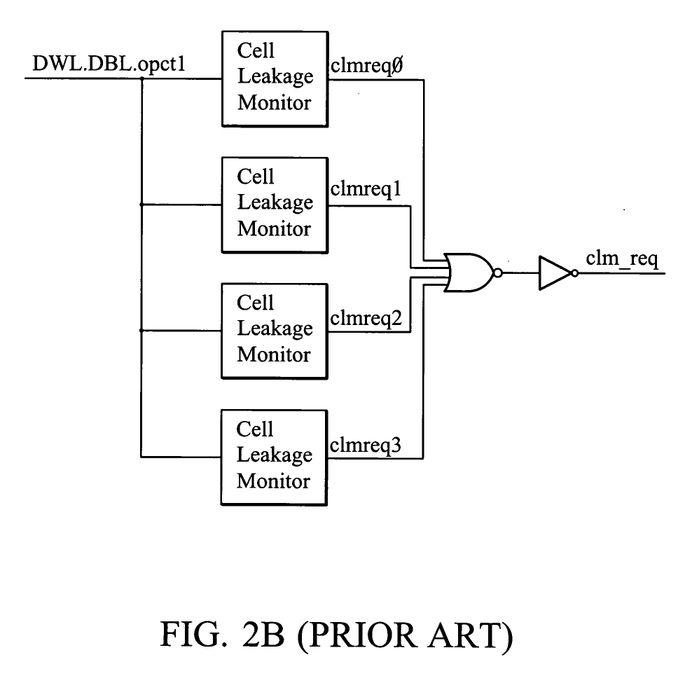

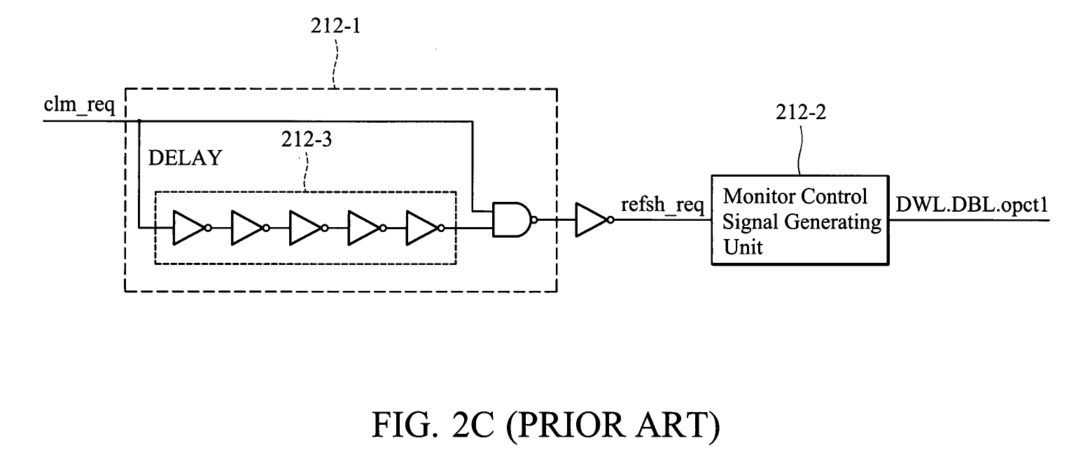

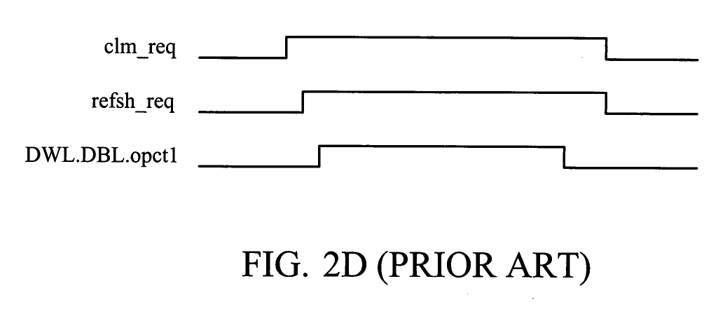

### DETAILED DESCRIPTION OF THE INVENTION

Disclosed herein are novel systems and methods for a memory device without junction leakage. To facilitate description of the inventive system, an example system that can be used to implement the memory device is discussed with reference to the figures. Although this system is described in detail, it will be appreciated that this system is provided for purpose of illustration only and that various modifications are feasible without departing from the inventive concept. After the example system has been described, an example of operation of the system will be provided to explain the manner in which the system can be used to provide the memory device without junction leakage.

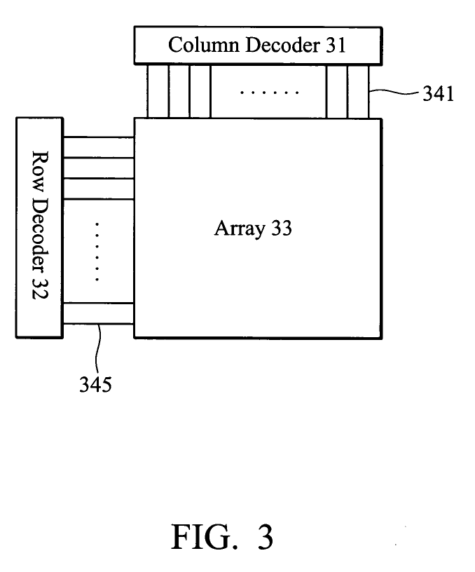

Referring now in more detail to the drawings, FIG. 3 is a diagram showing a memory device according to a preferred embodiment of the invention. The memory device generally includes an array 33 composed of rows and columns of memory cells, a column decoder 31 coupled to the memory cells in the array 33 through bit lines 341 and a row decoder 32 coupled to the memory cells in the array 33 through word lines 345. The row decoder 32 may select a word line 345 in the array 33 when a write, read or refresh is performed. The row decoder 32 receives an address and row enable signal. When the row enable signal is asserted, the row decoder 32 can activate a word line 345 corresponding to the received address. The column decoder 31 may select a bit line 341 when a write or read is performed. The column decoder 31 receives an address and column enable signal. When the column enable signal is asserted, the column decoder 31 can select a bit line 341 corresponding to the received address.

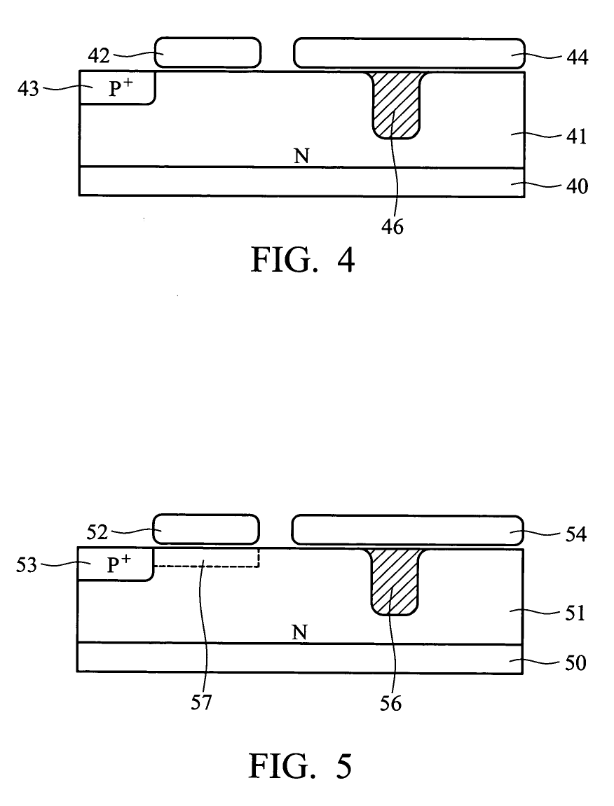

FIG. 4 shows a memory cell in the array according to a first preferred embodiment of the invention. The cell includes a P substrate 40, N well 41, transfer gate 42, P source/drain doped region 43, poly gate (plate) 44 and STI (Shallow Trench Isolation) 46. The N well 41 is formed in the P substrate 40 and coupled to receive a voltage V_{dd}. The transfer gate 42 is formed on the P substrate 40 and coupled to one of the word lines 345 (shown in FIG. 3). The P source/drain doped region 43 is formed in the N well 41 and on one side of the transfer gate 42, and coupled to one of the bit lines 341 (shown in FIG. 3). The poly plate 44 is formed on the P substrate 40 and another side of the transfer gate 42, and coupled to receive a voltage V_{BB}. The voltage V_{BB} applied to the poly plate 44 forms an inversion region in the N well 41 under the poly plate 44. Thus, the inversion region functions as a storage node holding the charge for data retention. Since there is no physical P/N junction between the storage node and the N well 41, no junction leakage occurs. Further, the word line 345 is coupled to receive the voltage V_{BB} when the cell is nt B selected while the word line 345 is coupled to receive a voltage V_{PP} higher than the voltage V_{dd} when the cell is not selected.

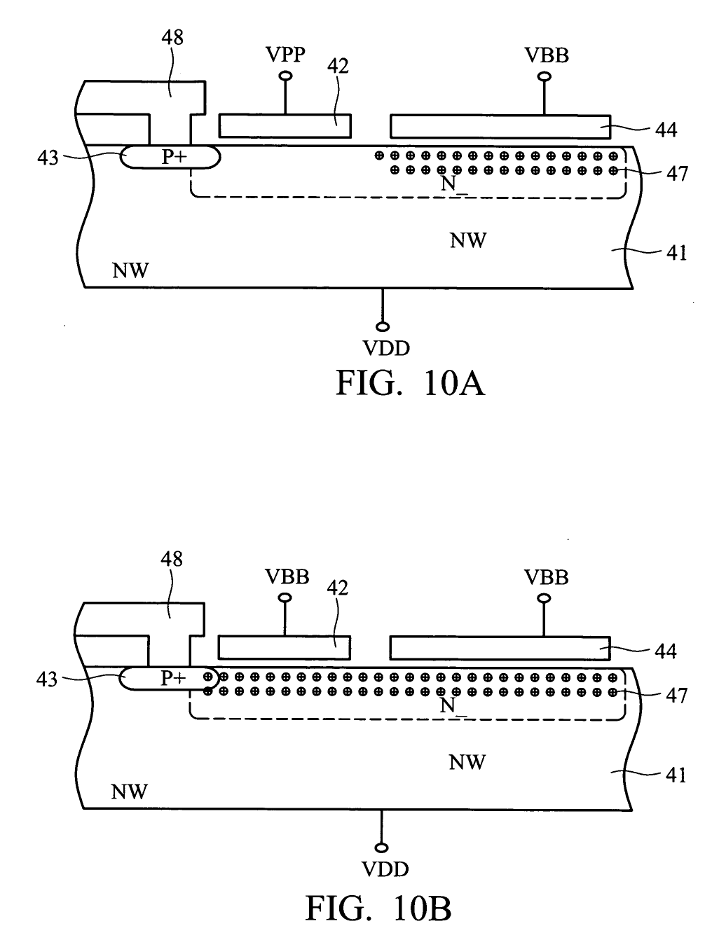

FIGS. 10A and 10B are diagrams showing the operation of the memory cell in FIG. 4. As shown in FIG. 10A, when the transfer gate 42 receives the voltage V_{PP} (i.e., the memory cell is not selected), majority carriers (holes) 47 are expelled from the portion under the transfer gate 42, which prevents the data bit hold in the inversion region form being read through the bit line 48. On the other hand, as shown in FIG. 10B, when the transfer gate 42 receives the voltage V_{BB} (i.e., the memory cell is selected), the inversion region extends through the portion under the transfer gate 42 to the source region 43, which makes it possible to read the data bit through the bit line 48. This achieves a dynamic channel length under the transfer gate 42 by a native device (without additional drain doping area in the N well 41).

FIG. 5 shows a memory cell in the array according to a second preferred embodiment of the invention. The cell includes a P substrate 50, N well 51, transfer gate 52, P source/drain doped region 53, poly gate (plate) 54 and STI (Shallow Trench Isolation) 56. The N well 51 is formed in the P substrate 50 and coupled to receive a voltage V_{dd}. The transfer gate 52 is formed on the P substrate 50 and coupled to one of the word lines 345. The P source/drain doped region 53 is formed in the N well 51 and on one side of the transfer gate 52, and coupled to one of the bit lines 341. The poly plate 54 is formed on the P substrate 50 and another side of the transfer gate 52, and coupled to receive a voltage V_{BB}. The voltage V_{BB} applied to the poly plate 54 forms an inversion region in the N well 51 under the poly plate 54. Thus, the inversion region functions as a storage node holding the charge for data retention. Since there is no physical P/N junction between the storage node and the N well 51, no junction leakage occurs. Further, the word line 345 is coupled to receive the voltage V_{BB} when the cell is not selected while the word line 345 is coupled to receive a voltage V_{PP} higher than the voltage V_{dd} when the cell is not selected. Additionally, there is a channel implantation region 57 under the transfer gate 52, which helps to reduce the sub-threshold current.

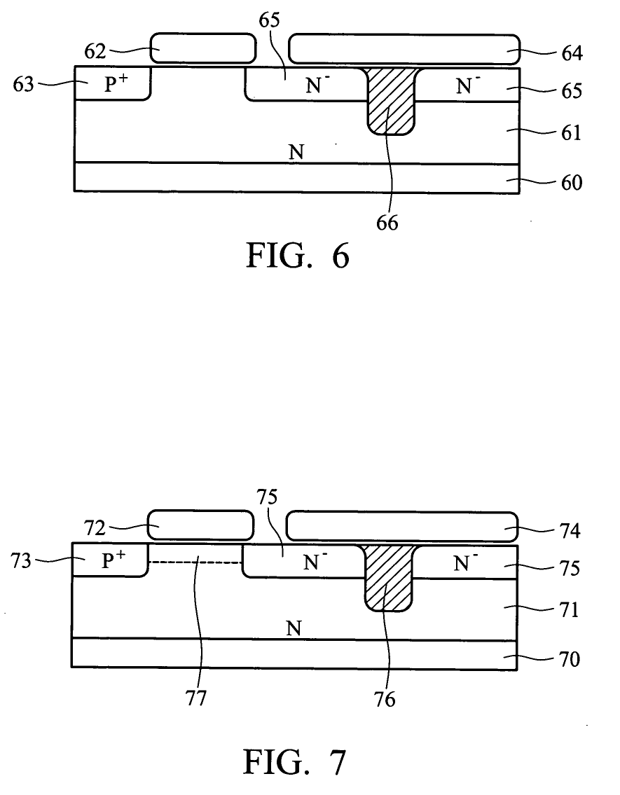

FIG. 6 shows a memory cell in the array according to a third preferred embodiment of the invention. The cell includes a P substrate 60, N well 61, transfer gate 62, P source/drain doped region 63, poly gate (plate) 64 and low-Vt device 65 and STI (Shallow Trench Isolation) 66. The N well 61 is formed in the P substrate 60 and coupled to receive a voltage V_{dd}. The transfer gate 62 is formed on the P substrate 60 and coupled to one of the word lines 345 (shown in FIG. 3). The P source/drain doped region 63 is formed in the N well 61 and on one side of the transfer gate 62, and coupled to one of the bit lines 341 (shown in FIG. 3). The poly plate 64 is formed on the P substrate 60 and another side of the transfer gate 62, and coupled to receive a voltage V_{BB}. The low-Vt device 65 is formed by a low Vt implantation step and has a threshold voltage around zero. In this embodiment, the low-Vt device 65 is an N-doped region in the N well 61. In order to eliminate a barrier possibly formed within the spacing between the gates 62 and 64, the N-doped region extends to the portion under the transfer gate 62. The concentration of the N-doped region is lower that that of the N well 61. The voltage V_{BB} applied to the poly plate 64 forms an inversion region in the N-doped region under the poly plate 64. Thus, the inversion region functions as a storage node holding the charge for data retention. Since there is no physical P/N junction between the storage node and the N well 61, no junction leakage occurs. Further, the word line 345 is coupled to receive the voltage V_{BB} when the cell is selected while the word line 345 is coupled to receive a voltage V_{PP} higher than the voltage V_{dd} when the cell is not selected.

FIG. 7 shows a memory cell in the array according to a fourth preferred embodiment of the invention. The cell includes a P substrate 70, N well 71, transfer gate 72, P source/drain doped region 73, poly gate (plate) 74, low-Vt device 75 and STI (Shallow Trench Isolation) 76. The N well 71 is formed in the P substrate 70 and coupled to receive a voltage V_{dd}. The transfer gate 72 is formed on the P substrate 70 and coupled to one of the word lines 345 (shown in FIG. 3). The P source/drain doped region 73 is formed in the N well 71 and on one side of the transfer gate 72, and coupled to one of the bit lines 341 (shown in FIG. 3). The poly plate 64 is formed on the P substrate 70 and another side of the transfer gate 72, and coupled to receive a voltage V_{BB}. The low-Vt device 75 is formed by a low Vt implantation step and has a threshold voltage around zero. In this embodiment, the low-Vt device is an N-doped region in the N well 71. In order to eliminate a barrier possibly formed within the spacing between the gates 72 and 74, the N-doped region extends to the portion under the transfer gate 72. The concentration of the N-doped region is lower that that of the N well 71. The voltage V_{BB} applied to the poly plate 74 forms an inversion region in the N-doped region under the poly plate 74. Thus, the inversion region functions as a storage node holding the charge for data retention. Since there is no physical P/N junction between the storage node and the N well 71, no junction leakage occurs. Further, the word line 345 is coupled to receive the voltage V_{BB} when the cell is selected while the word line 345 is coupled to receive a voltage V_{PP} higher than the voltage V_{dd} when the cell is not selected. Additionally, there is a channel implantation region 67 under the transfer gate 62, which helps to reduce the sub-threshold current.

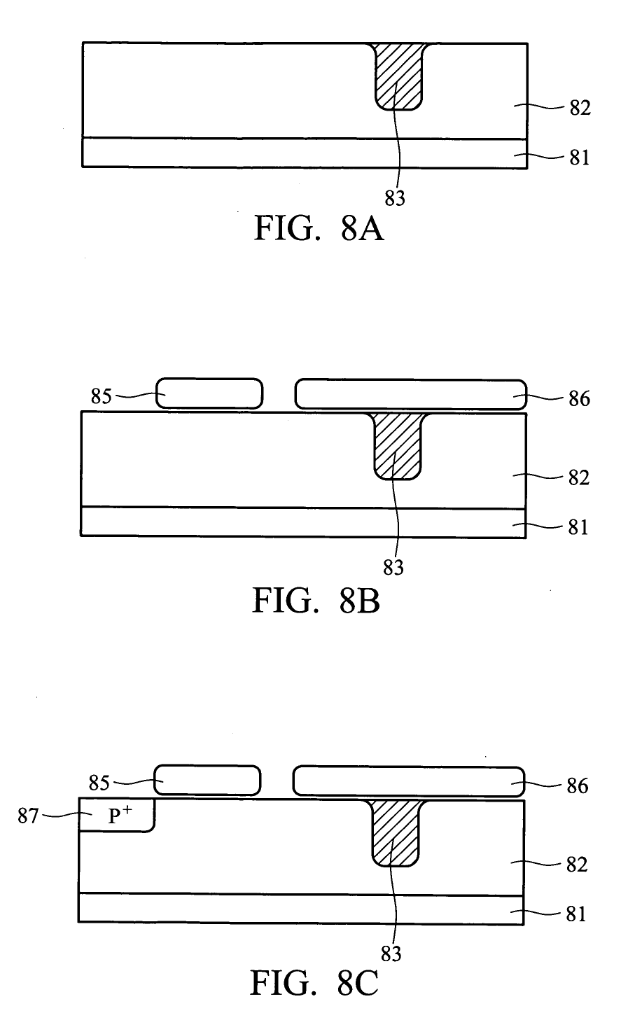

FIGS. 8A-8C are diagrams showing a series of views of a one-transistor random access memory cell during a manufacturing process according to a preferred embodiment of the invention.

As shown in FIG. 8A, a P substrate 81 is provided. By ion implantation, an N well 82 is formed in the P substrate 81. Next, an isolation region 83 is formed in the P substrate 81. The isolation region may be an STI.

As shown in FIG. 8B, poly-silicon layer is deposited on the P substrate 81 and patterned to form a transfer gate 85 and poly plate 86 on the P substrate 81.

As shown in FIG. 8C, by ion implantation, a P source/drain region 87 is formed in the N well 82 and on another side of the transfer gate 85.

In an alternative embodiment, a channel implantation region (not shown) is formed under the transfer gate 85, which helps to reduce the sub-threshold current.

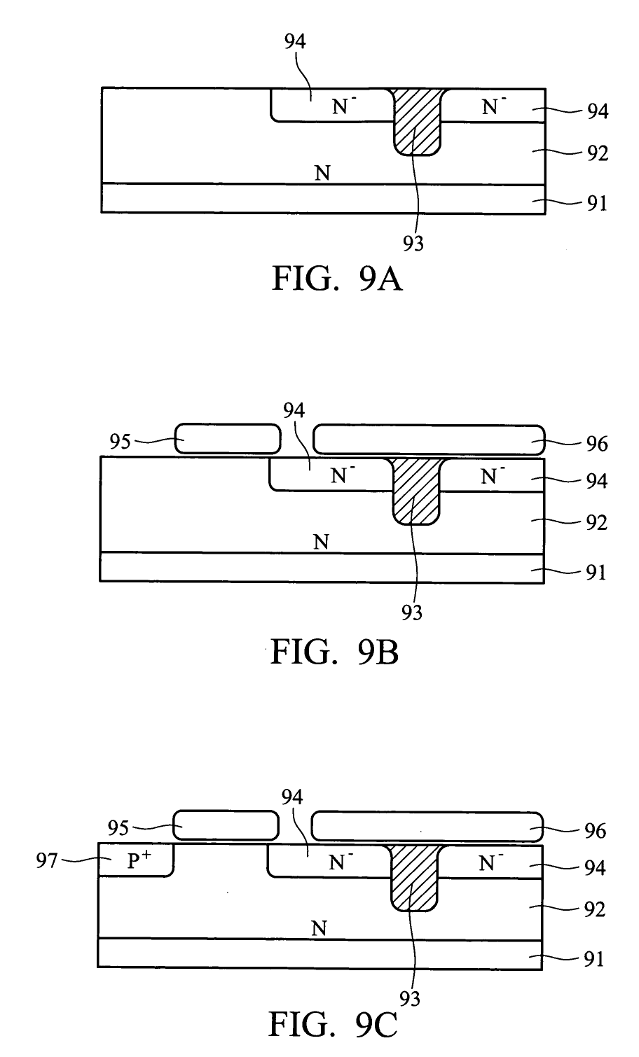

FIGS. 9A-9C are diagrams showing a series of views of a one-transistor random access memory cell during a manufacturing process according to another preferred embodiment of the invention.

As shown in FIG. 9A, a P substrate 91 is provided. By ion implantation, an N well 92 is formed in the P substrate 91. An isolation region 93 is formed in the P substrate 91. The isolation region may be an STI. Further, N-doped regions 94 are formed in the N well 92.

As shown in FIG. 9B, poly-silicon layer is deposited on the P substrate 91 and patterned to form a transfer gate 95 and poly plate 96 on the P substrate 91. The poly plate 96 is located above the N-doped region 94, and the N-doped region 94 is located on one side of the transfer gate 95 and extends to the portion under the transfer gate 95.

As shown in FIG. 9C, by ion implantation, a P source/drain region 97 is formed in the N well 92 and on another side of the transfer gate 95.

In an alternative embodiment, Additionally, a channel implantation region (not shown) is formed under the transfer gate 95, which helps to reduce the sub-threshold current.

The present invention provides a 1T-RAM cell without junction leakage, wherein refresh frequency is reduced significantly. The storage node is implemented by a native device or low-Vt device. There is no physical junction on the storage node so that no junction leakage occurs. Thus, the frequency of the refresh operation for data retention is reduced.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

1. A one-transistor random access memory cell comprising:
a substrate;
a well of a first conductivity type formed in the substrate and coupled to receive a first voltage;
a first gate formed on the substrate and coupled to a word line;
a doped region of a second conductivity type formed in the well and on a first side of the first gate, and coupled to a bit line; and
a second gate formed on the substrate and a second side of the first gate, and coupled to receive a second voltage;
such that the second voltage applied to the second gate forms an inversion region in the well under the second gate.

2. The one-transistor random access memory cell as in claim 1, wherein the first and second conductivity types are N and P type respectively.

3. The one-transistor random access memory cell as in claim 1, wherein the first and second voltages are Vdd and VBB respectively.

4. The one-transistor random access memory cell as in claim 1, wherein the word line is coupled to receive the second voltage when the cell is not selected and the word line is coupled to receive a third voltage higher than the first voltage when the cell is selected.

5. The one-transistor random access memory cell as in claim 1 further comprising a channel implantation region in the well under the first gate.

6. A one-transistor random access memory cell comprising:
a substrate;
a well of a first conductivity type formed in the substrate and coupled to receive a first voltage;
a first gate formed on the substrate and coupled to a word line;
a first doped region of a second conductivity type formed in the well and on a first side of the first gate, and coupled to a bit line;
a second gate formed on the substrate and a second side of the first gate, and coupled to receive a second voltage; and
a second doped region of the first type in the well under the second gate having a doping concentration lower than that of the well.

7. The one-transistor random access memory cell as in claim 6, wherein the first and second conductivity types are N and P type respectively.

8. The one-transistor random access memory cell as in claim 6, wherein the first and second voltages are Vdd and VBB respectively.

9. The one-transistor random access memory cell as in claim 6, wherein the word line is coupled to receive the second voltage when the cell is selected and the word line is coupled to receive a third voltage higher than the first voltage when the cell is not selected.

10. The one-transistor random access memory cell as in claim 6 further comprising a channel implantation region in the well under the first gate.

11. A memory device comprising:
a plurality of memory cells wherein data is read from and written into each of the memory cells through bit lines by control signals on word lines, each of the memory cells comprising:
a substrate;
a well of a first conductivity type formed in the substrate and coupled to receive a first voltage;
a first gate formed on the substrate and coupled to one of the word lines;
a doped region of a second conductivity type formed in the well and on a first side of the first gate, and coupled to one of the bit lines; and
a second gate formed on the substrate and a second side of the first gate, and coupled to receive a second voltage;
such that the second voltage applied to the second gate forming an inversion region in the well under the second gate.

12. The memory device as in claim 11, wherein the first and second conductivity types are N and P type respectively.

13. The memory device as in claim 11, wherein the first and second voltages are Vdd and VBB respectively.

14. The memory device as in claim 11, wherein the word line is coupled to receive the second voltage when the cell is selected and the word line is coupled to receive a third voltage higher than the first voltage when the cell is not selected.

15. The memory device as in claim 11 further comprising a channel implantation region in the well under the first gate.

16. A memory device comprising:
a plurality of memory cells wherein data is read from and written into each of the memory cells through bit lines by control signals on word lines, each of the memory cells comprising:
a substrate;
a well of a first conductivity type formed in the substrate and coupled to receive a first voltage;
a first gate formed on the substrate and coupled to a word line;
a first doped region of a second conductivity type formed in the well and on a first side of the first gate, and coupled to a bit line;
a second gate formed on the substrate and a second side of the first gate, and coupled to receive a second voltage; and
a second doped region of the first type in the well under the second gate having a doping concentration lower than that of the well.

17. The memory device as in claim 16, wherein the first and second conductivity types are N and P type respectively.

18. The memory device as in claim 16, wherein the first and second voltages are Vdd and VBB respectively.

19. The memory device as in claim 16, wherein the word line is coupled to receive the second voltage when the cell is selected and the word line is coupled to receive a third voltage higher than the first voltage when the cell is not selected.

20. The memory device as in claim 16 further comprising a channel implantation region in the well under the first gate.

21. A method for manufacturing a one-transistor random access memory cell, comprising the steps of:
providing a substrate;
forming a well of a first conductivity type in the substrate;
forming a first and second gate on the substrate, such that the second gate is located on a first side of the first gate; and
forming a doped region of a second conductivity type in the well and on a second side of the first gate.

22. The method as in claim 21, wherein the first and second conductivity types are N and P type respectively.

23. A method for manufacturing a one-transistor random access memory cell, comprising the steps of:
providing a substrate;
forming a well of a first conductivity type in the substrate;
implementing low Vt implantation to form a low-Vt device in the well;
forming a first and second gate on the substrate, such that the second gate is located above the low-Vt device and the low-Vt device is located on a first side of the first gate; and
forming a doped region of a second conductivity type in the well and on a second side of the first gate.

24. The method as in claim 23, wherein the first and second conductivity types are N and P type respectively.
